(19) United States
(12) Patent Application Publication
(10) Pub. No.: US 2014/0217430 A1
(43) Pub. Date: Aug. 7, 2014

(54) OPTOELECTRONIC SEMICONDUCTOR UNIT AND MODULE COMPRISING A PLURALITY OF SUCH UNITS

(71) Applicants: Hailing Cui, Regensburg (DE); Ion Stoll, Tegernheim (DE)

(72) Inventors: Hailing Cui, Regensburg (DE); Ion Stoll, Tegernheim (DE)

(73) Assignee: OSRAM OPTO SEMICONDUCTORS GMBH, Regensburg (DE)

(21) Appl. No.: 14/129,521

(22) PCT Filed: Jun. 20, 2012
(86) PCT No.: PCT/EP2012/061822

§ 371 Date: Apr. 3, 2014

(30) Foreign Application Priority Data
Jul. 4, 2011 (DE) 102011106478.1

(51) Int. Cl. H01L 33/50; H01L 27/15

(52) U.S. Cl. CPC H01L 33/50; H01L 27/153
USPC 257/89

(57) ABSTRACT

A semiconductor unit (10) is provided which comprises a first semiconductor chip (1a) and a second semiconductor chip (1b). The first and second semiconductor chip (1a, 1b) each have an active layer (1a, 1b) suitable for generating radiation. A first converter (3a) which comprises a yellow phosphor with an added red phosphor is arranged downstream of the first semiconductor chip (1a). A second converter (3b) which comprises a yellow phosphor with an added green phosphor is arranged downstream of the second semiconductor chip (1b). A module having a plurality of such units (10) is also provided.

The invention relates to an optoelectronic unit which comprises a first semiconductor chip and a second semiconductor chip. The present invention also relates to a module comprising a plurality of such semiconductor units.

This patent application claims the priority of the German patent application 102011106478.1, the disclosure content of which is hereby incorporated by reference.

In order to back-light display screens, such as e.g. televisions and computer monitors, LEDs are often used which have LCD-filters connected downstream thereof in the radiating direction. There are different requirements for the LEDs. On the one hand, a maximum brightness of the LEDs and on the other hand a large colour gamut are expected. The properties of the LEDs can be adapted by means of different converters which are connected downstream of the LEDs in the radiating direction. However, the desired properties, such as e.g. brightness and colour gamut, generally behave in an opposed manner with respect to each other. For example, converters which convert in the green or red wavelength range do not have the brightness of yellow converters but have a larger colour gamut than yellow converters.

Furthermore, the technical properties of the different LCD-filters produce for the individual LEDs different white points which must be achieved for an optimum colour gamut. The mixing of e.g. two converters produces the colour range, which can be achieved, from the degree of conversion between the wavelength of the radiation emitted by the LED and the dominance wavelength of the converter, which can contain a plurality of phosphors, and the transmission of the LCD-filter connected downstream. However, in this case the dominance wavelength of the converter consisting of a plurality of phosphors can only be varied at the limits of the dominance wavelength of the individual phosphors. In order then to achieve the greatest possible brightness, the dominance wavelength should be close to the sensitivity curve of the human eye. However, this frequently means that only a defined region of white points can be achieved with a converter optimised to the brightness, thus facilitating optimum brightness but a reduced colour gamut.

In addition, as a result of production fluctuations identical LED products frequently do not have exactly identical levels of brightness and chromaticity coordinates. In relation to this, it is known to classify LEDs into classes in terms of their physical parameters, wherein LEDs of various classes are installed together in a display screen. Then, they produce overall on the display screen plane an averaged brightness and an averaged chromaticity coordinate. By means of this so-called champing, LEDs of the most varied classifications are thus installed in an end product.

The object of the present invention is to provide an optoelectronic semiconductor unit which is suitable for back-lighting, wherein the semiconductor chips of the semiconductor unit have a maximum brightness and at the same time an increased colour gamut.

This object is achieved by a semiconductor unit having the features of claim 1. This object is also achieved by a use of such a semiconductor unit having the features of claim 11. Furthermore, this object is achieved by a module comprising a plurality of such semiconductor units having the features of claim 12. Advantageous developments of the semiconductor unit, its use and of the module are described in the dependent claims.

In accordance with at least one embodiment, the optoelectronic semiconductor unit comprises a first semiconductor chip and a second semiconductor chip, wherein the first semiconductor chip and the second semiconductor chip each have an active layer suitable for generating radiation. A first converter which comprises a yellow phosphor with an added red phosphor is arranged downstream of the first semiconductor chip in the radiating direction. A second converter which comprises a yellow phosphor with an added green phosphor is arranged downstream of the second semiconductor chip in the radiating direction.

Therefore, the first converter contains a yellow phosphor and additionally a red phosphor. Correspondingly, the second converter contains a yellow phosphor and additionally a green phosphor.

Different converters having at least partially different phosphors are thus arranged downstream of the individual semiconductor chips of the unit. The radiation of the second semiconductor chip is at least partially converted by the second converter into yellow and green radiation.

The radiation of the first semiconductor chip is converted at least partially by the first converter into yellow and red radiation. A maximum brightness can be achieved in an advantageous manner through the respective use of a yellow phosphor. By using two further, different phosphors, namely the green phosphor and the red phosphor, which are installed in the same semiconductor unit, it is possible in an advantageous manner to achieve a desired white point with an increased colour gamut. In particular, a very large region of white points can be achieved in an advantageous manner on LED level by virtue of the different dominance wavelengths of the total of three phosphors.

The individual radiations which are emitted by the individual semiconductor chips and are converted at the converters arranged downstream preferably have a similar chromaticity coordinate. In a preferred manner, the radiation emitted by the first semiconductor chip and converted at the first converter is in the ultra-white wavelength range with a proportion of red radiation. The radiation emitted by the second semiconductor chip and converted at the second converter is preferably in the ultra-white wavelength range with a proportion of green radiation.

In accordance with the invention, an emission spectrum of the unit can thus be produced which is composed of a superposition of the individual emitted or converted spectra of the semiconductor chips or converters which is advantageously adapted to the conventional LCD-filter systems. This facilitates a maximum brightness and an increased colour gamut for the back-lighting of e.g. display screens.

The semiconductor unit is an optoelectronic unit which permits the conversion of electrically generated data or energies into light emission or vice versa. The semiconductor unit has two optoelectronic semiconductor chips, preferably radiation-emitting semiconductor chips. The semiconductor chips are preferably LEDs, particularly preferably thin-film LEDs. In particular, in the case of thin-film LEDs, a growth substrate, on which layers of the semiconductor chips have been epitaxially grown, is partially or completely detached.

The semiconductor chips each have a semiconductor layer stack, in which the active layer is contained. The active layer preferably contains a pn-transition, a dual heterostructure, a single quantum well structure (SQW) or a multi quantum well structure (MQW) for generating radiation. In this case, the designation “quantum well structure” does not provide any indication of the dimensionality of the quantisation. It includes inter alia quantum wells, quantum wires and quantum dots and every combination of these structures.

The semiconductor layer stack of the semiconductor chips preferably contains in each case a III/V-semiconductor material. III/V-semiconductor materials are particularly suitable for generating radiation in the ultraviolet to visible to infrared spectral ranges.

In accordance with at least one embodiment, the active layer of the first and second semiconductor chip is suitable in each case for emitting radiation in the blue wavelength range. This blue radiation is then converted at the first converter or at the second converter into yellow and red or yellow and green radiation, so that the unit emits white radiation overall.

In accordance with at least one embodiment, the first and second converters are each suitable for converting a portion of the radiation, which is emitted by the first or second semiconductor chip, into radiation at least of another wavelength, and for transmitting in an unconverted manner a portion of the radiation emitted by the first or second semiconductor chip.

The phrase “transmitted in an unconverted manner” means in this case that the radiation emitted by the first or second semiconductor chip passes at least partially without interaction through the first or second converter, so that this proportion of the radiation leaves the corresponding converter as blue radiation. The converters are thus not suitable for complete conversion but rather convert merely a portion of the radiation emitted by the respective semiconductor chip.

In accordance with at least one embodiment, the yellow phosphor is a Y₃(Ga_{X}Al_{1-X})₅O₁₂-based phosphor, in particular a Y₃(Ga_{X}Al_{1-X})₅O₁₂:Ce-based phosphor. The red phosphor is preferably a Eu²⁺-doped CaAlSiN₃:-based phosphor or a (Ba,Sr,Ca)₂Si₅N₈-based phosphor. The green phosphor is preferably an Eu²⁺-doped orthosilicate or nitride orthosilicate, an Lu₃(Ga_{X}Al_{1-X})₅O₁₂-based phosphor, in particular an Lu₃(Ga_{X}Al_{1-X})₅O₁₂:Ce-based phosphor, a Y₃Al₅O₁₂:Ce-based phosphor, a (Ba,Sr)Si₂O₂N₂-based phosphor or an β-SiAlON-based phosphor. In particular, semiconductor chips having such phosphors or phosphor combinations connected downstream have an optimum brightness and a large colour gamut. Moreover, these phosphors are advantageously cost-effective.

In accordance with at least one embodiment, the first converter and/or the second converter are formed as converter platelets. Converter platelets have e.g. a matrix material with the phosphors embedded therein. By means of e.g. one layer transfer, the separately produced converter platelets can be applied to the semiconductor chips. Such converter platelets are also known to the person skilled in the art by the term phosphor layer.

In accordance with at least one embodiment, the semiconductor unit also has a housing with at least one cavity, in which the semiconductor chips are arranged. In this case, the semiconductor unit is formed as an LED-package. Alternatively, it is possible for each semiconductor chip in the housing to be allocated a cavity, wherein each semiconductor chip is thus arranged in a separate cavity of the housing.

In accordance with at least one embodiment, the semiconductor unit also has an optical element which is arranged downstream of the semiconductor chips in the radiating direction. In this case, the semiconductor unit does not necessarily have to comprise a housing. In this case, the semiconductor chips can be mounted e.g. on a planar printed circuit board.

Preferably, the radiation emitted by the first semiconductor chip and the radiation emitted by the second semiconductor chip and the radiation emitted by the converters are coupled into the optical element. The spectral components of the converted and unconverted radiation can thus be mixed in the optical element, so that white light is advantageously produced.

In accordance with at least one embodiment, the optical element is a light guide. This light guide is preferably suitable for back-lighting of televisions and computer monitors or other display screens. Preferably, the light guide is formed in such a manner that a homogeneous directional characteristic is achieved. For this purpose, the light guide contains e.g. scattering centres which are preferably suitable for scattering the spectral components, which are coupled into the light guide, homogeneously in all spatial directions.

In accordance with at least one embodiment, the semiconductor unit is used as back-lighting.

In accordance with at least one embodiment, a module comprises a plurality of semiconductor units which are arranged on a common support substrate, wherein a light guide is arranged downstream of the semiconductor units in the radiating direction. The radiation emitted by the individual semiconductor units is coupled in this case into the common light guide. With respect to the homogeneous directional characteristic, scattering centres are preferably integrated in the light guide and are suitable for scattering the radiation emitted by the semiconductor units.

Preferably, the module is used for the back-lighting e.g. of a display screen.

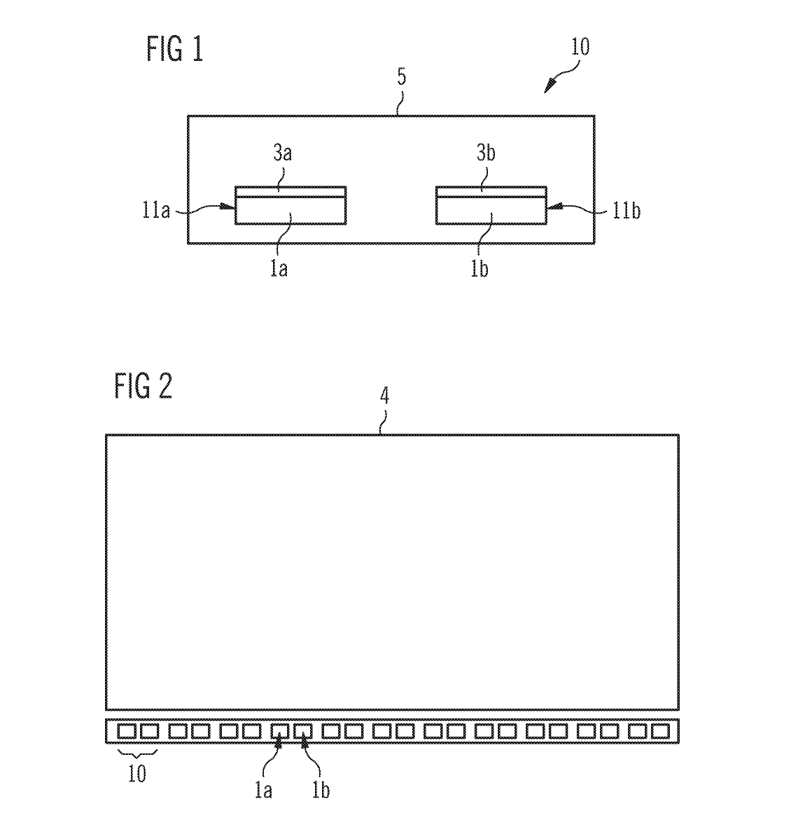

Further advantages and advantageous developments of the invention will be apparent from the exemplified embodiments described hereinafter in conjunction with FIGS. 1 to 3, in which:

FIG. 1 shows a schematic cross-section of an exemplified embodiment of a semiconductor unit in accordance with the invention,

FIG. 2 shows a schematic cross-section of an exemplified embodiment of a module in accordance with the invention, and

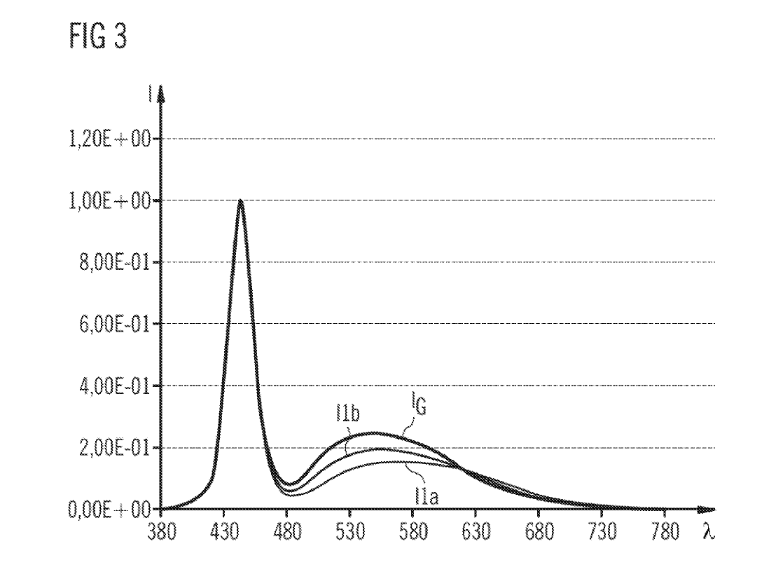

FIG. 3 shows a graph illustrating the emission spectra of a semiconductor unit in accordance with the invention and its semiconductor chips as a function of the wavelength.

In the Figures, like parts, or parts acting in an identical manner, can be provided with the same reference numerals in each case. The illustrated elements and the size ratios of the elements with respect to each other are not to be regarded as being to scale. Rather, individual elements, such as e.g. layers, structures, components and regions, may be illustrated excessively thick or large for better clarity and/or for ease of understanding.

FIG. 1 illustrates a cross-section of an exemplified embodiment of a semiconductor unit 10 which has a housing 5. The housing 5 has a support substrate (not illustrated) which is surrounded e.g. by means of the housing 5. The housing 5 has a cavity (not illustrated), in which a first semiconductor chip 1a and a second semiconductor chip 1b are arranged. In particular, the semiconductor chips 1a, 1b are mounted directly on the support substrate on a base surface of the cavity of the housing 5.

The first semiconductor chip 1a has an active layer 11a which is suitable for generating radiation and is suitable for emitting radiation in the blue wavelength range. The second semiconductor chip 1b has a layer 11b which is suitable for generating radiation and is likewise suitable for emitting radiation in the blue wavelength range. The semiconductor chips 1a, 1b each have a semiconductor layer sequence based upon a III/V-semiconductor material. The active layer 11a, 11b is integrated in each case in the semiconductor layer sequence. The semiconductor chips 1a, 1b are preferably LEDs.

Arranged downstream of the first semiconductor chip 1a in the radiating direction is a first converter 3a which is suitable for converting radiation in the blue wavelength range into radiation in the yellow wavelength range. In addition, the first converter 3a has a red phosphor which is suitable for converting the blue radiation, which is emitted by the first semiconductor chip 1a, into radiation in the red wavelength range.

In the present case, the first converter 3a is formed as a converter platelet and is arranged directly on a radiation coupling-out side of the first semiconductor chip 1a. For this purpose, e.g. the converter platelet 3a is produced separately and is transferred by means of a layer transfer onto the first semiconductor chip 1a where it is affixed. The first converter 3a converts preferably the radiation, which is emitted by the first semiconductor chip 1a, partially into radiation in the yellow and red wavelength range. This means that only a partial conversion takes place in the first converter 3a, so that beams passing through from the first converter 3a comprise a blue proportion and a yellow and red proportion. For example, about 50% of the radiation emitted by the active layer 11a of the first semiconductor chip 1a is converted in the first converter 3a into yellow or red radiation and about 50% is transmitted in an unconverted manner as blue radiation.

The yellow phosphor of the first converter 3a is preferably a Y₃(Ga_{X}Al_{1-X})₅O₁₂:Ce-based phosphor. The red phosphor is preferably an Eu²⁺-doped CaAlSiN₃:-based phosphor or a (Ba,Sr,Ca)₂Si₅N₈-based phosphor.

A second converter 3b, which is likewise formed as a converter platelet, is correspondingly arranged on the second semiconductor chip 1b and is arranged downstream of the semiconductor chip in the radiating direction. The second converter 3b converts a portion of the radiation, which is emitted by the second semiconductor chip 1b, into radiation in the yellow and green wavelength range. A portion of the radiation emitted by the second semiconductor chip 1b is transmitted by the second converter 3b in an unconverted manner as blue radiation. Beams passing through from the second converter 3b thus comprise a yellow and green proportion and a blue proportion. For example, again, about 50% of the radiation, which is emitted by the active layer 11b of the second semiconductor chip 1b, is converted in the second converter 3b into yellow or green radiation and about 50% is transmitted in an unconverted manner.

The yellow phosphor of the second converter 3b is, again, preferably a Y₃(Ga_{X}Al_{1-X})₅O₁₂:Ce-based phosphor. The green phosphor of the second converter 3b is preferably an Eu²⁺-doped orthosilicate or nitride orthosilicate, an Lu₃(Ga_{X}Al_{1-X})₅O₁₂:Ce-based phosphor, a Y₃Al₅O₁₂:Ce-based phosphor, a (Ba,Sr)Si₂O₂N₂-based phosphor or a β-SiAlON-based phosphor. If the green phosphor is a Y₃Al₅O₁₂:Ce-based phosphor, then it preferably has a low doping of less than 1%.

The converters 3a, 3b each preferably have a matrix material, in which the individual phosphors are embedded. In a particularly preferable manner, the individual phosphors of the converters 3a, 3b are distributed homogeneously in the matrix material, so that a directional characteristic which is as homogeneous as possible can be achieved.

The semiconductor unit of FIG. 1 emits on the whole blue radiation, which is emitted by the semiconductor chips 1a, 1b and transmitted in an unconverted manner, red and yellow radiation, which is converted by the first converter 3a, and green and yellow radiation which is converted by the second converter 3b. As a result, a unit can be produced whose emission spectrum has an increased colour space in comparison with the individual semiconductor chips 1a, 1b at maximum brightness. Such units are thus particularly suitable for the back-lighting of display screens, such as e.g. televisions and computers.

By using the aforementioned converters 3a, 3b, a high colour gamut with maximum brightness can be achieved in an advantageous manner.

The semiconductor unit does not necessarily have to comprise a housing. Alternatively, the semiconductor chips 1a, 1b can be applied on a support substrate which is not surrounded by a housing.

FIG. 2 illustrates an exemplified embodiment of a module which comprises a plurality of semiconductor units 10 which are arranged e.g. next to one another on a support substrate 2. The semiconductor units 10 of FIG. 2 can be configured e.g. in each case corresponding to the semiconductor unit in accordance with the exemplified embodiment of FIG. 1. The units thus have two semiconductor chips 1a, 1b in each case, downstream of each of which are arranged the first converter 3a and second converter 3b respectively. The first and second semiconductor chips 1a, 1b are preferably disposed in an alternating manner on the support substrate.

A common optical element 4 is arranged downstream of the semiconductor chips 1a, 1b of the units 10 in the radiating direction. The optical element 4 is e.g. a light guide which preferably contains scattering centres. The scattering centres are preferably suitable for scattering the radiation, which is emitted by the semiconductor units 10, homogeneously in all spatial directions.

The beams emitted by the semiconductor chips 1a, 1b of the semiconductor units 10 and the converted beams are coupled collectively into the common light guide 4, wherein the spectral components of the radiation are mixed in the light guide 4. In particular, the blue radiation emitted by the first semiconductor chip 1a, the yellow and red radiation converted by the first converter 3a, the blue radiation emitted by the second semiconductor chip 1b and the yellow and green radiation converted by the second converter 3b are coupled collectively into the light guide 4 where they are preferably homogeneously mixed. Such beams which are coupled-in in a light guide and mixed therein can be used for the back-lighting of e.g. televisions and computer monitors.

FIG. 3 illustrates a graph, in which standardised radiation emission I is plotted against the wavelength λ of an semiconductor unit in accordance with the invention, e.g. in accordance with the exemplified embodiment of FIG. 1. The graph shows the emission spectrum I1a of the radiation which is emitted by the first semiconductor chip and converged at the first converter, the emission spectrum I1b of the radiation which is emitted by the second semiconductor chip and converged at the second converter, and the emission spectrum IG of the radiation emitted in total by the semiconductor unit. The emission spectrum IG is in particular the summed spectrum of the individual emission spectra I1a, I1b of the individual semiconductor chips of the unit.

By virtue of the different dominance wavelengths of the total of three phosphors used in the yellow, red and green wavelength range, a very large region of white points can be achieved in an advantageous manner on LED level. On display screen level, this advantageously leads to an increased colour gamut in comparison with the individual semiconductor chips at maximum brightness.

The invention is not limited by the description using the exemplified embodiments. Rather, the invention includes any new feature and any combination of features included in particular in any combination of features in the claims, even if this feature or this combination itself is not explicitly stated in the claims or exemplified embodiments.

1. Optoelectronic semiconductor unit which comprises a first semiconductor chip and a second semiconductor chip, wherein
the first semiconductor chip has an active layer which is suitable for generating radiation,
the second semiconductor chip has an active layer which is suitable for generating radiation,
a first converter which comprises a yellow phosphor with an added red phosphor is arranged downstream of the first semiconductor chip in the radiating direction, and
a second converter which comprises a yellow phosphor with an added green phosphor is arranged downstream of the second semiconductor chip in the radiating direction.

2. Semiconductor unit according to claim 1, wherein the active layer of the first semiconductor chip and the active layer of the second semiconductor chip are each suitable for emitting radiation in the blue wavelength range.

3. Semiconductor unit according to claim 1, wherein
the first and second converters are each suitable for converting a portion of the radiation, which is emitted by the first or second semiconductor chip, into radiation at least of another wavelength, and for transmitting in an unconverted manner a portion of the radiation emitted by the first or second semiconductor chip.

4. Semiconductor unit according to claim 1, wherein the yellow phosphor is a Y₃(Ga_{X}Al_{1-X})₅O₁₂:Ce-based phosphor.

5. Semiconductor unit according to claim 1, wherein the red phosphor is an Eu²⁺-doped CaAlSiN₃:-based phosphor or a (Ba,Sr,Ca)₂Si₅N₈-based phosphor.

6. Semiconductor unit according to claim 1, wherein the green phosphor is an Eu²⁺-doped orthosilicate or nitride orthosilicate, an Lu₃(Ga_{X}Al_{1-X})₅O₁₂:Ce-based phosphor, a Y₃Al₅O₁₂:Ce-based phosphor, a (Ba,Sr)Si₂O₂N₂-based phosphor or a β-SiAlON-based phosphor.

7. Semiconductor unit according to claim 1, wherein the first converter and the second converter are formed as converter platelets.

8. Semiconductor unit according to claim 1, further comprising a housing with at least one cavity, in which the semiconductor chips are arranged.

9. Semiconductor unit according to claim 1, further comprising an optical element which is arranged downstream of the semiconductor chips in the radiating direction.

10. Semiconductor unit according to claim 9, wherein the optical element is a light guide which contains scattering centres.

11. Semiconductor unit according to claim 1, wherein the first converter comprises only two phosphors.

12. Module, which comprises a plurality of semiconductor units according to claim 1, which are arranged on a common support substrate, wherein a light guide is arranged downstream of the semiconductor units in the radiating direction.

13. Module according to claim 12, wherein scattering centres which are suitable for scattering the radiation emitted by the semiconductor units are integrated in the light guide.

14. Semiconductor unit according to claim 1, wherein the second converter comprises only two phosphors.

15. Optoelectronic semiconductor unit which comprises a first semiconductor chip and a second semiconductor chip, wherein
the first semiconductor chip has an active layer which is suitable for generating radiation,
the second semiconductor chip has an active layer which is suitable for generating radiation,
a first converter which comprises a yellow phosphor with an added red phosphor is arranged downstream of the first semiconductor chip in the radiating direction,
a second converter which comprises a yellow phosphor with an added green phosphor is arranged downstream of the second semiconductor chip in the radiating direction,
the radiation emitted by the first semiconductor chip and converted at the first converter corresponds to white light with a proportion of red radiation, and
the radiation emitted by the second semiconductor chip and converted at the second converter corresponds to white light with a proportion of green radiation.
